(19) United States
(12) Patent Application Publication
(10) Pub. No.: US 2009/0199902 A1
(43) Pub. Date: Aug. 13, 2009

(54) SILICON SOLAR CELLS COMPRISING LANTHANIDES FOR MODIFYING THE SPECTRUM AND METHOD FOR THE PRODUCTION THEREOF

(75) Inventor: Dirk Habermann, Kirchzarten (DE)

Correspondence Address: AKERMAN SENTERFITT, P.O. BOX 3188, WEST PALM BEACH, FL, 33402-3188, US

(73) Assignee: SCHMID TECHNOLOGY SYSTEMS GMBH, NIEDERESCHACH (DE)

(21) Appl. No.: 12/306,622

(22) PCT Filed: May 31, 2007
(86) PCT No.: PCT/EP07/04807

§ 371 Date: Mar. 20, 2009

(30) Foreign Application Priority Data
Jun. 29, 2006 (DE) 10 2006 031 300.3

(51) Int. Cl. H01L 31/0288; H01L 21/322; H01L 21/265; H01L 21/22; H01L 29/167

(52) U.S. Cl. 136/261; 438/513; 438/514; 438/542; 257/607; 257/E21.135; 257/E21.335; 257/E21.318; 257/E29.086

(57) ABSTRACT

The aim of the invention is to improve the energy yield efficiency of solar cells. According to the invention, the silicon material is doped with one or more different lanthanides such that said material penetrates into a layer approximately 60 nm deep. Photons, whose energy is at least double that of the 1.2 eV silicon material band gap, are thus converted into at least two photons having energy in the region of the silicon band gap, by excitation and recombination of the unpaired 4f electrons of the lanthanides. As a result, additional photons having advantageous energy close to the silicon band gap are provided for electron-hole pair formation.

### FIELD OF APPLICATION AND PRIOR ART

The invention relates to a method for doping silicon material for solar cells, as well as silicon material doped with a corresponding method, as well as solar cells made from such a silicon material.

Due to the character of silicon as an “indirect semiconductor” it only has weak light-emitting properties at ambient temperature. An intense electroluminescence can only be detected at temperatures around 20 K. Therefore the good absorption characteristics of silicon in the wavelength range 400 to 1200 nm is the basis making it particularly suitable as a starting material for photovoltaic processes.

Silicon doped with the elements boron and phosphorus has a characteristic light absorption. The characteristic property of lanthanides is the almost complete shielding of the unpaired electrons of the 4f orbitals from the surrounding crystal field by outer shell electrons. Thus, independently of the crystal field, the energy levels of the excitation states of these unpaired electrons is largely constant. Despite a limited interaction with the crystal field the conditional probability for the population of said energy levels is highly influenced by the crystal field and is apparent in the different quantum efficiency of the emission bands as a function of the crystal structure. In a completely different technical field lanthanides are known as luminescence activators in natural and technical phosphors.

### PROBLEM AND SOLUTION

The problem of the invention is to provide an aforementioned method, a silicon material and solar cells making it possible to obviate the problems of the prior art and in particular improve an energy efficiency of a finished solar cell.

This problem is solved by a method having the features of claim 1, a silicon material having the features of claim 23 and a solar cell made from such a silicon material having the features of claim 27. Advantageous and preferred developments of the invention form the subject matter of the further claims and are explained in greater detail hereinafter. Some of the following features are only enumerated once. However, independently of this, they can apply both to the method, the silicon material and the finished solar cell. By express reference the wording of the claims is made into part of the content of the description.

The silicon material to be doped is present in a flat form, namely as a wafer or the like, as is known. According to the invention lanthanides are doped into a top layer or a top region of the silicon material which is less than 1 μm in order to consequently modify the absorption characteristics of the silicon material. This can take place both for monocrystalline and for multicrystalline solar cells.

Through the incorporation of lanthanides into said silicon structures or further structures of the solar cell, as well as in mixed phases from said structures, it is possible to achieve a more efficient utilization of the UV and near UV radiation of sunlight. This is to take place in such a form that from a photon with an energy at least twice higher than the band gap of silicon (1.12 eV) through excitation and recombination of the unpaired 4f electrons of the lanthanides two or more photons with energies only slightly higher than the band gap of silicon (1.12 eV) or equal thereto are formed. The main emission line of silicon is in a range below 1.12 eV. The extrinsic photoluminescence can then contribute to the generation of electrical energy, in that then additional photons are available with energies close to the silicon gap for electron-hole pair formation. The photons arising through the excitation and recombination of electrons of lanthanides are intended to directly contribute to the formation of electron-hole pairs in p or n-silicon.

Advantageously the lanthanides or the corresponding doping material are applied to the top layer or to the surface of the silicon material. This has the advantage that the application process is simple and in addition the conversion of the aforementioned photons in the top layer of the silicon material can be utilized particularly well for the subsequent generation of electrical energy. To this extent the doping of the top layer of the silicon material or the solar cell is particularly advantageous.

In a development of the invention the lanthanides can be introduced into a layer on the silicon material or the actual silicon material, which is only partly made from silicon. One possibility is an antireflection layer or a Si₃N₄ layer. A further possibility is a TCO layer, i.e. light-transmitting, electrically conductive oxide material, e.g. ZnO or TiO. A further possible layer is of carbon nanotubes (CNT), which can be applied to the solar cell silicon. A further possible layer is of amorphous silicon (a-silicon), in certain cases also in conjunction with SiOₓ or SiO₂. In such an aforementioned case with the introduction into a layer only partly formed from silicon, the lanthanides can also be incorporated in mineral phases with an oxygen-ligand field.

In a further development of the invention lanthanides can be doped in to the region of the pn junction of the silicon material. This is also effective in generating photons in the vicinity of the band gap of silicon from photons with a much higher energy.

In a further development of the invention lanthanides can be doped into the region of the back surface field, i.e. the back of the silicon material.

In a further development of the invention the lanthanides can be doped into a silicon material layer essentially comprising SiO₂.

The diffusion processes used in present Si-solar cell production with the presence of free oxygen and nitrogen under high temperatures can also form structures or phases in or at the interface to the silicon or in the silicon material such as:
1. lanthanide-oxygen clusters
2. Si—B—P—O-lanthanide phases
3. lanthanide-Si—O—N-phases or their mixed phases.

These regions which, strictly speaking are not pure Si-lanthanide compounds, can also contribute to a rise in efficiency through the above-described process of lanthanide-coupled electron hole-pair formation. Another aim is for the diffusion process to produce oxygen clusters in conjunction with lanthanides in a silicon-dominated structure and thereby permit the photoluminescence known for many lanthanides with emission in the visible range of the spectrum (400-800 nm).

A diffusion of the introduced lanthanides in the pn-junction close to the solar cell surface can be used in targeted manner for forming p-dominated O-lanthanide structures or clusters. One possibility is to diffuse the lanthanides into the silicon material. Another possibility consists of applying the lanthanides in a sputtering process. For this purpose use can be made of conventional sputtering sources and application devices.

In another development of the invention a doping with lanthanides can take place in that they are contained in an aqueous solution or a gel, which is applied to the silicon material. This is then advantageously followed by themostatting for diffusing in.

In yet another development of the invention the lanthanides can be applied by a gas phase process or a CVD process.

In a further development of the invention it is possible to use a plasma process for applying and diffusing the lanthanides into the silicon material.

In another development of the invention the lanthanides can be applied by condensation, i.e. by deposition from a gas-like phase. This can take place without thermostatting, but this is considered advantageous for diffusing in the lanthanides.

In a further development of the invention the lanthanides can be applied by solid state contact, i.e. by direct lanthanide material application.

In another development of the invention doping of the silicon material with lanthanides can take place by ion implantation.

In a further development of the invention the lanthanides can be doped into the silicon material from a lanthanide-doped layer on said silicon material, advantageously under thermal action or by thermostatting.

Following such an application of lanthanides, in a further step the silicon material or the surface can be thermostatted. This can be used for a better diffusing in of the doping material, but is not absolutely necessary.

Several lanthanides can be used for the material in question, but it is also possible to use a single lanthanide material. It is also possible to use combinations of different lanthanides for doping, which are then jointly present. Suitable lanthanides are in particular those whose main emission lines are in the visible range of light, i.e. somewhat below 1.2 eV and are constituted by La, Ce, Pr, Nd, Pm, Sm, Eu, Gd, Tb, Dy, Ho, Er, Tm, Yb and Lu. However, advantageously within the scope of the present invention Er is excluded from the lanthanides used. Doping with lanthanides can also take place coupled with that of other doping elements, e.g. Mn2+. Particularly due to the fact that the main emission line is in the visible range of light, the light absorption in the silicon material in the UV and near UV range can be improved, not only in the silicon material per se, but also in the p and n-doped silicon, in silicon-oxygen clusters, in SiO(x) and in Si₃N₄. The light absorption in different mineral phases of the silicon material can also be improved.

In a further development of the invention a diffusing in of lanthanides takes place with a depth of less than 1 μm, e.g. only 500 to 600 nm, so that the diffusion process can be made simpler. Moreover a less deep diffusing in is considered adequate.

It is possible for a layer resulting from doping with lanthanides to occur in the silicon material and can also form an independent layer. As stated hereinbefore, this layer is advantageously located relatively high up in the silicon material or the finished solar cell.

The inventive silicon material is inventively produced using a method with the aforementioned possibilities. An inventive solar cell can then be built up from such a silicon material.

These and further features can be gathered from the claims and description and the individual features, both singly or in the form of subcombinations, can be implemented in an embodiment of the invention and in other fields and can represent advantageous, independently protectable developments for which protection is claimed here. The subdivision of the application into individual sections and the subheadings in no way restrict the general validity of the statements made thereunder.

1. A method for doping silicon material for solar cells, the silicon material being present in flat form as a wafer or the like, the method comprising doping lanthanides into a top layer or a top region of less than 1 μm for modifying the absorption characteristics of the silicon materiel.

2. The method according to claim 1, wherein the lanthanides or the doping material are applied to the top layer or the surface.

3. The method according to claim 1, wherein the lanthanides are introduced into a layer mainly comprising Si₃N₄ on silicon for solar cells.

4. The method according to claim 1, wherein the lanthanides are introduced into a TCO layer on silicon for solar cells.

5. The method according to claim 1, wherein the lanthanides are introduced into a transparent carbon nanotube layer on silicon for solar cells.

6. The method according to claim 1, wherein the lanthanides are introduced into a layer on amorphous silicon for solar cells, said layer preferably largely comprising Si₃N₄.

7. The method according to claim 1, wherein the lanthanides are introduced into the region of the pn junction of silicon for solar cells.

8. The method according to one claim 1, wherein the lanthanides are introduced into the region of the back surface field of silicon for solar cells.

9. The method according to claim 1, wherein the lanihanides are introduced into a layer mainly comprising SiO₂ on silicon for solar cells.

10. The method according to claim 1, wherein the lanthanides are diffused into the silicon material.

11. The method according to claim 1, wherein the lanihanides are applied or introduced into the silicon material by a sputtering process.

12. The method according to claim 1, wherein the lanthanides are applied to or introduced into the silicon material as an aqueous solution or gel.

13. The method according to claim 1, wherein the lanthanides are applied to or introduced into the silicon material by a gas phase process.

14. The method according to claim 1, wherein the lanthanides are applied to or introduced into the silicon material by a plasma process.

15. The method according to claim 1, wherein the lanthanides are applied to or introduced into the silicon material by condensation.

16. The method according to claim 1, wherein the lanthanides are applied to or introduced into the silicon material by solid state contact.

17. The method according to claim 1, wherein the lanthanides are applied to or introduced into the silicon material by ion implantation.

18. The method according to claim 1, wherein the lanthanides are applied to or introduced into the silicon material via lanthanide-doped layers and a subsequent diffusion of the lanthanides into the silicon material.

19. The method according to claim 1, wherein thermostatting is carried out following the application of the lanthanides to or into the silicon material.

20. The method according to claim 1, wherein erbium is excluded from the lanthanides used.

21. The method according to claim 1, wherein the lanthanides are diffused less than 1000 nm deep into the silicon material, preferably by 500 to 600 nm.

22. The method according to claim 1, wherein the lanthanide-doped layer preferably forms an independent layer within a silicon material layer.

23. A silicon material in the form of wafers or the like for the production of solar cells, wherein it is doped with lanthanides using a method according to claim 1.

24. The silicon material according to claim 23, wherein erbium is excluded from the lanthanides used.

25. The silicon material according to claim 23, wherein the lanthanides are diffused less than 1000 nm deep into the silicon material and preferably by 500 to 600 nm.

26. The silicon material according to claim 23, wherein the lanthanide-doped layer preferably forms an independent layer within a silicon material layer.

27. A solar cell having or made from a silicon material according to claim 23.
